(19) United States
(12) Patent Application Publication
(10) Pub. No.: US 2012/0025335 A1
(43) Pub. Date: Feb. 2, 2012

(54) MICROELECTROMECHANICAL SYSTEMS (MEMS) PACKAGE

(75) Inventors: Timothy LECLAIR, Longmont, CO (US); Steve MARTIN, Fort Collins, CO (US); David MARTIN, Fort Collins, CO (US); Atul GOEL, Fort Collins, CO (US)

(73) Assignee: Avago Technologies Wireless IP (Singapore) Pte. Ltd., Singapore (SG)

(21) Appl. No.: 13/029,314

(22) Filed: Feb. 17, 2011

Related U.S. Application Data
(63) Continuation-in-part of application No. 12/844,857, filed on Jul. 28, 2010.

(51) Int. Cl. H01L 29/84

(52) U.S. Cl. 257/416; 257/E29.324

(57) ABSTRACT

A micro-electromechanical systems (MEMS) transducer device comprises: a package substrate having a first coefficient of thermal expansion (CTE); and a transducer substrate comprising a transducer. The transducer substrate is disposed over the package substrate. The transducer substrate has a second CTE that substantially matches the first CTE.

### CROSS-REFERENCE TO RELATED APPLICATIONS

The present application is a continuation-in-part under 37 C.F.R. § 1.53(b) of and claims priority under 35 U.S.C.§120 from commonly owned U.S. patent application Ser. No. 12/844,857 entitled “MEMS Transducer Device having Stress Mitigation Structure and Method of Fabricating the Same” filed on Jul. 28, 2010 to Timothy LeClair, et al. The disclosure of this application is specifically incorporated herein by reference.

### BACKGROUND

Transducers generally convert electrical signals to mechanical signals or vibrations, and/or mechanical signals or vibrations to electrical signals. Acoustic transducers, in particular, convert electrical signals to acoustic signals (sound waves) in a transmit mode (e.g., a speaker application), and/or convert received acoustic waves to electrical signals in a receive mode (e.g., a microphone application). Transducers, such as ultrasonic transducers, are provided in a wide variety of electronic applications, including filters. As the need to reduce the size of many components continues, the demand for reduced-size transducers continues to increase, as well. This has led to comparatively small transducers, which may be micromachined according to various technologies, such as micro-electromechanical systems (MEMS) technology.

Various types of MEMS transducers, such as piezoelectric ultrasonic transducers (PMUTs), include a resonator stack, having a layer of piezoelectric material between two conductive plates (electrodes), formed on a thin membrane. The membrane may be formed on a substrate over a cavity passing through the substrate. Typically, the substrate is formed of a material compatible with semiconductor processes, such as silicon (Si). The transducers may be packaged by polishing the back side of the transducer substrate and mounting the polished transducer substrate directly onto a package substrate. For example, when the transducer is to be included in a lead frame package, the transducer substrate is typically mounted on a metal package substrate.

In known packaging, a coefficient of thermal expansion (CTE) of the transducer is significantly different from the CTE of the package in which it is mounted. Generally, CTE indicates the rate or proportion of change of a material or structure with respect to changes in temperature. The difference between the transducer and package CTEs results in varying responses to changes in temperature, both during packaging processes and during operation, which impose physical stress on the transducer. In other words, the source of parametric shifts in MEMS bending mode and/or thickness mode transducers due to die mounting and operating temperature variation, for example, is mismatch of thermal properties between the materials of the transducer and the package. The stress is most pronounced between the transducer substrate and the package substrate to which the transducer substrate is attached, due to the intimate physical contact and significant CTE mismatch of the respective materials.

After the MEMS transducer is packaged, the package is aligned to and mounted on a system-level printed circuit board. In known MEMS packaging, the alignment process adds complexity to the fabrication process and often does not provide suitable alignment of the MEMS transducer.

What is needed is a MEMS package that overcomes at least the shortcomings of known MEMS packages described above.

### SUMMARY

In a representative embodiment, a micro-electromechanical systems (MEMS) transducer device is mounted to a substrate. The MEMS transducer device comprises: a package substrate having a first coefficient of thermal expansion (CTE); and a transducer substrate comprising a transducer, the transducer substrate being disposed over the package substrate, wherein the transducer substrate has a second CTE that is substantially the same as the first CTE.

In another representative embodiment, a micro-electromechanical systems (MEMS) transducer device comprises: a package substrate having a first coefficient of thermal expansion (CTE); and a transducer substrate comprising a transducer, the transducer substrate being disposed over the package substrate, wherein the transducer substrate has a second CTE that is substantially the same as the first CTE.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIGS. 1A and 1B are isometric exploded views of a MEMS package, according to a representative embodiment.

FIGS. 2A-2B are isometric exploded views of a MEMS package, according to a representative embodiment.

FIG. 3 is a cross-sectional view of a MEMS package mounted to a substrate, according to a representative embodiment.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the representative embodiments. Such methods and apparatuses are clearly within the scope of the present teachings.

Generally, it is understood that the drawings and the various elements depicted therein are not drawn to scale. Further, relative terms, such as “above,” “below,” “top,” “bottom,” “upper,” “lower,” “left,” “right,” “vertical” and “horizontal,” are used to describe the various elements' relationships to one another, as illustrated in the accompanying drawings. It is understood that these relative terms are intended to encompass different orientations of the device and/or elements in addition to the orientation depicted in the drawings. For example, if the device were inverted with respect to the view in the drawings, an element described as “above” another element, for example, would now be “below” that element. Likewise, if the device were rotated 90 degrees with respect to the view in the drawings, an element described as “vertical,” for example, would now be “horizontal.”

According to various embodiments, a transducer device, such as a MEMS ultrasonic transducer or a PMUT, comprises a package substrate having a first coefficient of thermal expansion (CTE); a transducer comprising an active area disposed over a transducer substrate, the transducer substrate having a second CTE that is substantially the same as the first CTE; and an opening in the package substrate configured to receive and to transmit mechanical waves from the transducer.

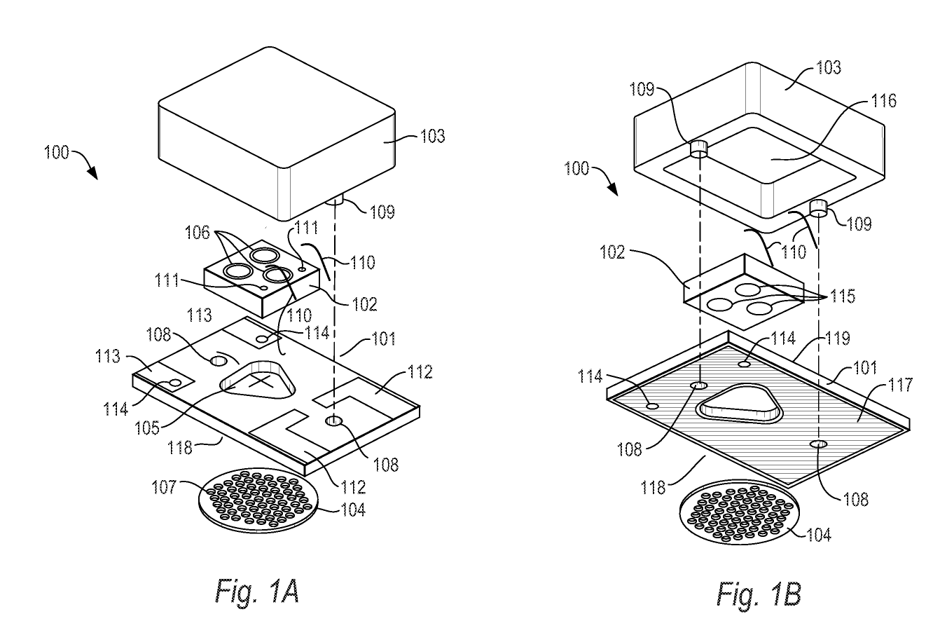

FIG. 1A is an isometric exploded view of a MEMS transducer device 100, according to a representative embodiment. The MEMS transducer device 100 comprises a package substrate 101, a transducer substrate 102, a cover 103 and a screen 104. As described more fully below, an opening 105 in the package substrate 101 is configured to receive and to transmit mechanical waves (e.g., ultrasonic waves) to and from a plurality of transducers 106 provided over the transducer substrate 102.

In the presently illustrated embodiment, there are three (3) transducers 106. It is emphasized that this is merely illustrative, and that more or fewer transducers 106 may be provided over the transducer substrate 102. The transducers 106 may be ultrasonic MEMS transducers, for example, although it is understood that other types of transducers may be incorporated without departing from the scope of the present teachings. The transducers 106 are shown as annular resonators, where the cross-section is taken across the center. The transducers 106 may be substantially circular in shape, for example, although other shapes are contemplated including, but not limited to ovals, squares, rectangles, or the like, without departing from the scope of the present teachings.

The transducer substrate 102 comprises silicon (Si), or silicon-germanium (SiGe), or silicon-on-insulator (SOD, or gallium arsenide (GaAs), or indium phosphide (InP), or sapphire, or alumina, or doped SiO₂ (e.g., borosilicate glass (BSG) or Pyrex®). Among other considerations, the material selected for the transducer substrate 102 is useful for integrating electrical connections and electronics, thus reducing size and cost. In representative embodiments, the package substrate 101 may be alumina, sapphire, or a comparatively high density ceramic material within the purview of one of ordinary skill in the art having had the benefit of review of the present disclosure. The material selected for the package substrate 101 is selected to provide a CTE that substantially matches to the CTE of the transducer substrate 102. In particular, the CTE of the package substrate 101 is selected to be as close to the CTE of the transducer substrate 102 as possible, while taking into account other desired material properties such as ease of fabrication of useful features thereon (e.g., metallization, contacts, openings), ease of integrating electrical connections and electronics, reliability and cost. For example, in a representative embodiment, the transducer substrate 102 is silicon (Si), which has a CTE of approximately 3.0 ppm/° C., and the package substrate 101 is alumina, which has a CTE of approximately 6.0 ppm/° C.

In representative embodiments, the transducers 106 may be PMUTs fabricated using MEMS technology. Further details of the components and configurations of the transducers 106 may be found in commonly owned U.S. patent application Ser. No. 12/844,857 entitled “MEMS Transducer Device having Stress Mitigation Structure and Method of Fabricating the Same” filed on Jul. 28, 2010 to Timothy LeClair, et al. The disclosure of this application is specifically incorporated herein by reference. Generally, examples of methods, materials and structures for fabricating transducers 106 are described in commonly owned U.S. Pat. Nos. 5,587,620, 5,873,153, 6,384,697 and 7,275,292 to Ruby, et al.; commonly owned U.S. Pat. No. 6,828,713 to Bradley; in commonly owned U.S. Patent Application Pub. Nos. 2008/0122320 and 2008/0122317 to Fazzio, et al; in commonly owned U.S. Patent Application Pub. No. 2007/0205850 to Jamneala, et al; in commonly owned U.S. Patent Application Pub. No. 2008/0258842 to Ruby, et al; in commonly owned U.S. Patent Application Pub. No. 2006/0103492 to Feng, et al.; and in commonly owned U.S. patent application Ser. no. 12/495,443 to Martin, et al. The disclosures of these commonly owned patents, patent application publications and patent applications are specifically incorporated herein by reference.

When the transducers 106 are PMUTs, for example, the translation is made through a piezoelectric material (not shown). In various alternative embodiments, the MEMS transducer device 100 may be any type of micromachined transducer with a membrane having stress as a significant parameter, such as a capacitive micro-machined ultrasonic transducer (CMUT), in which case the translation is made through a capacitance variation. It is understood that other types and arrangements of transducers may be incorporated, without departing from the scope of the present teachings.

Cover 103 is provided over the package substrate 101 and surrounds the transducer substrate 102. Among other functions, the cover 103 provides protection from debris from contacting the transducers 106. In a representative embodiment, the cover 103 comprises plastic, aluminum, steel, copper, brass or other suitable material. As described more fully herein, the cover is sized to fit through an opening in a circuit board (not shown in FIG. 1A) or other substrate to which the MEMS transducer device 100 is mounted.

Openings 108 are provided in the package substrate 101 and located to receive a respective post 109 (only one post 109 can be seen in FIG. 1A) for securing the cover 103 over the transducer substrate 102 and to the package substrate 101. The openings 108 may extend through the package substrate 101 and are formed by laser drilling or other known techniques. A suitable adhesive may be used to secure the posts 109 to the package substrate 101.

Screen 104 is provided over opening 105 in the package substrate 101. The screen 104 comprises a plurality of holes 107 so that mechanical waves emitted from or incident on the transducers 106 can traverse the screen 104 without significant interference or impedance. The screen 104 protects the transducers 106 from debris or other objects that can deleteriously impact the performance of the transducers 106. Illustratively, the screen 104 comprises the same material as the package substrate 101. The holes 107 are machined into a blank substrate by a known laser drilling method. Illustratively, the holes 107 have a diameter of 0.015 in (15 mils). Generally, when using laser drilling techniques to form the holes 107, the diameter of the holes 107 is substantially the same as the thickness of the package substrate 101.

In a representative embodiment, electrical connections to the transducers 106 are made with wirebonds 110 that connect contacts 111 on the transducer substrate 102 to contacts 112 on the package substrate 101. As described more fully below, the contacts 112 provide electrical connections to electrical circuitry and components useful in the transmission and reception of signals by the transducers 106. The contacts 111, 112 are provided over the transducer substrate 102 and the package substrate 101, respectively, by known metallization techniques. Illustratively, the contacts comprise a suitable conductive material such as gold (Au), copper (Cu) or aluminum (Al) or a suitable conductive alloy such as gold-tin alloy. Notably, the contacts 112 are partially covered by the cover 103, as can be appreciated from a review of FIG. 1A.

Connection pads 113 are provided over the package substrate 101, and vias 114 are provided through the package substrate. As described more fully below, the connection pads 113 contact connection pads on a circuit substrate (not shown in FIG. 1A) for securing (e.g., bonding) the MEMS transducer device 100 thereto. In an embodiment, the cover 103 is disposed at least partially over the connection pads 113 and vias 114. Illustratively, one or both of the connection pads 113 are connected by the vias 114 to a ground plane (described as a shield 117 below) to ensure properly grounding and to avoid “floating” grounds.

FIG. 1B is an isometric exploded view of MEMS transducer device 100, according to a representative embodiment. As FIG. 1B presents a different perspective of the MEMS transducer device 100 described above, details of many common aspects provided in the description of FIG. 1A are not repeated.

Transducer substrate 102 comprises cavities 115 aligned with respective transducers 106 (not visible in FIG. 1B). The cavities 115 provide a path for mechanical waves to and from the transducers 106. The cavities 115 are also aligned over the opening 105 in the package substrate 101 and the screen 104. The cavities 115 have a comparatively high-aspect ratio, and are formed by a known method such as dry reactive ion etching (DRIE), the so-called “Bosch method.” Many of the commonly-owned references incorporated by reference above provide details of the fabrication of the cavities 115 and are not generally repeated herein.

Cover 103 comprises a cavity 116 into which the transducer substrate 102 is disposed. As such, once assembled, the cover 103 encloses the transducer substrate 102. The cover 103 provides protection of the transducers 106 from debris and moisture. Furthermore, the depth of the cavity 116 is selected to provide an acoustic backplane for the transducers 106. Beneficially, the acoustic backplane fosters frequency stabilization of mechanical waves emanating from the transducers 106.

In a representative embodiment, a shield 117 is provided over a first side 118 of the package substrate 101 and opposing a second side 119 of the package substrate 101 over which the transducer substrate 102 is disposed. The shield 117 illustratively comprises a metal or metal alloy and is printed on the package substrate 101 by a known technique. The shield 117 provides a ground plane and prevents stray electromagnetic signals (e.g., RF signals) from adversely interfering with the operation of the transducers 106.

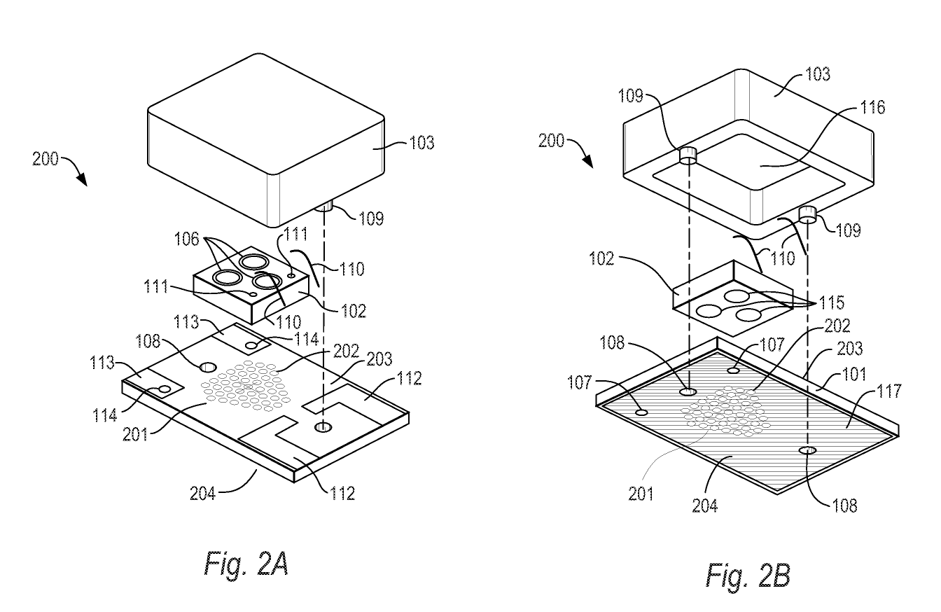

FIG. 2A is an isometric exploded view of a MEMS transducer device 200, according to a representative embodiment. The MEMS transducer device 200 comprises package substrate 101, transducer substrate 102 and cover 103 as described in connection with the representative embodiments of FIG. 1A. The MEMS transducer device 200 also comprises an integral screen 201. The integral screen 201 comprises a plurality of holes 202 that extend through a thickness of the package substrate from a first side 203 to a second side 204.

In the presently illustrated embodiment, there are three (3) transducers 106. It is emphasized that this is merely illustrative, and that more or fewer transducers 106 may be provided over the transducer substrate 102. The transducers 106 may be ultrasonic MEMS transducers, for example, although it is understood that other types of transducers may be incorporated without departing from the scope of the present teachings. The transducers 106 are shown as annular resonators, where the cross-section is taken across the center. The transducers 106 may be substantially circular in shape, for example, although other shapes are contemplated including, but not limited to ovals, squares, rectangles, or the like, without departing from the scope of the present teachings.

The transducer substrate 102 comprises silicon (Si), silicon-germanium (SiGe), silicon-on-insulator (SOD, gallium arsenide (GaAs), indium phosphide (InP), glass, sapphire, alumina, doped SiO₂ (e.g., borosilicate glass (BSG) or Pyrex®). Among other considerations, the material selected for the transducer substrate 102 is useful for integrating electrical connections and electronics, thus reducing size and cost. The material selected for the package substrate 101 is selected to provide a CTE that substantially matches the CTE of the transducer substrate 102. In particular, the CTE of the package substrate 101 is selected to be as close to the CTE of the transducer substrate 102 as possible, while taking into account other desired material properties such as ease of fabrication of useful features thereon (e.g., metallization, contacts, openings), ease of integrating electrical connections and electronics, reliability and cost. For example, in a representative embodiment, the transducer substrate 102 is silicon (Si), which has a CTE of approximately 3.0 ppm/° C., and the package substrate 101 is alumina, which has a CTE of approximately 6.0 ppm/° C.

In representative embodiments, the transducers 106 may be PMUTs fabricated using MEMS technology. Further details of the components and configurations of the transducers 106 may be found in the commonly owned U.S. Patents, U.S. Patent Application Publications and U.S. Patent Applications incorporated by reference herein.

When the transducers 106 are PMUTs, for example, the translation is made through a piezoelectric material (not shown). In various alternative embodiments, the MEMS transducer device 100 may be any type of micromachined transducer with a membrane having stress as a significant parameter, such as a capacitive micro-machined ultrasonic transducer (CMUT), in which case the translation is made through a capacitance variation. It is understood that other types and arrangements of transducers may be incorporated, without departing from the scope of the present teachings.

Cover 103 is provided over the package substrate 101 and surrounds the transducer substrate 102. Among other functions, the cover 103 provides protection from debris from contacting the transducers 106. In a representative embodiment, the cover 103 comprises plastic aluminum, steel, copper, brass or other suitable material. As described more fully herein, the cover is sized to fit through an opening in a circuit board (not shown in FIG. 1A) or other substrate to which the MEMS transducer device 100 is mounted.

Openings 108 are provided in the package substrate 101 and are located to receive respective post 109 (only one post 109 can be seen in FIG. 2A) for securing the cover 103 over the transducer substrate 102 and to the package substrate 101. The openings 108 may extend through the package substrate 101 from first side 203 to second side 204 and are formed by laser drilling or other known techniques. A suitable adhesive may be used to secure the posts 109 to the package substrate 101.

The transducer substrate 102 is disposed over integral screen 201. Integral screen 201 comprises a holes 202 extending from first side 203 to second side 204 so that mechanical waves emitted from or incident on the transducers 106 can traverse the integral screen 201 without significant interference or impedance. Integral screen 201 protects the transducers 106 from debris or other objects that can deleteriously impact the performance of the transducers 106. Illustratively, the screen 104 comprises the same material as the package substrate 101. The holes 202 are machined into package substrate 101 by a known laser drilling method. Illustratively, the holes 202 have a diameter of 0.015 in (15 mils). Generally, when using laser drilling techniques to form the holes 107, the diameter of the holes 107 is substantially the same as the thickness of the package substrate 101. The holes 202 have the same diameter as holes 107 in screen 104 described above in connection with the representative embodiments of FIGS. 1A-1B.

In a representative embodiment, electrical connections to the transducers 106 are made with wirebonds 110 that connect contacts 111 on the transducer substrate 102 to contacts 112 on the package substrate 101. As described more fully below, the contacts 112 provide electrical connections to electrical circuitry and components useful in the transmission and reception of signals by the transducers 106. The contacts 111, 112 are provided over the transducer substrate 102 and the package substrate 101, respectively, by known metallization techniques. Illustratively, the contacts comprise a suitable conductive material such as gold (Au), copper (Cu) or aluminum (Al) or a suitable conductive alloy such as gold-tin alloy. Notably, the contacts 112 are partially covered by the cover 103 as can be appreciated from a review of FIG. 1A.

Connection pads 113 are provided over the package substrate 101, and vias 114 are provided through the package substrate. As described more fully below, the connection pads 113 contact connections pads on a circuit substrate (not shown in FIG. 2A) for securing the MEMS transducer device 100 thereto. In an embodiment, the cover 103 is disposed at least partially over the connection pads 113 and vias 114. Illustratively, one or both of the connection pads 113 are connected by the vias 114 to a shield 117 to ensure properly grounding and to avoid “floating” grounds.

FIG. 2B is an isometric exploded view of MEMS transducer device 200, according to a representative embodiment. As FIG. 2B presents a different perspective of the MEMS transducer device 200 described above, details of many common aspects provided in the description of FIG. 2A are not repeated.

Transducer substrate 102 comprises cavities 115 aligned with respective transducers 106 (not visible in FIG. 2B). The cavities 115 provide a path for mechanical waves to and from the transducers 106. The cavities 115 are also aligned over the opening 105 in the package substrate 101 and the screen 104. The cavities 115 have a comparatively high-aspect ratio, and are formed by a known method such as dry reactive ion etching (DRIE), the so-called “Bosch method.” Many of the commonly-owned references incorporated above provide details of the fabrication of the cavities 115 and are not generally repeated herein.

Cover 103 comprises a cavity 116 into which the transducer substrate 102 is disposed. As such, once assembled, the cover 103 encloses the transducer substrate 102. The cover 103 provides protection of the transducers 106 from debris and moisture. Furthermore, the depth of the cavity 116 is selected to provide an acoustic backplane for the transducers 106. Beneficially, the acoustic backplane fosters frequency stabilization of mechanical waves emanating from the transducers 106.

In a representative embodiment, shield 117 is provided over the first side 203 of the package substrate 101. The shield 117 illustratively comprises a metal or metal alloy and is printed on the package substrate 101 by a known technique. The shield 117 provides a ground plane and prevents stray electromagnetic signals (e.g., RF signals) from adversely interfering with the operation of the transducers 106.

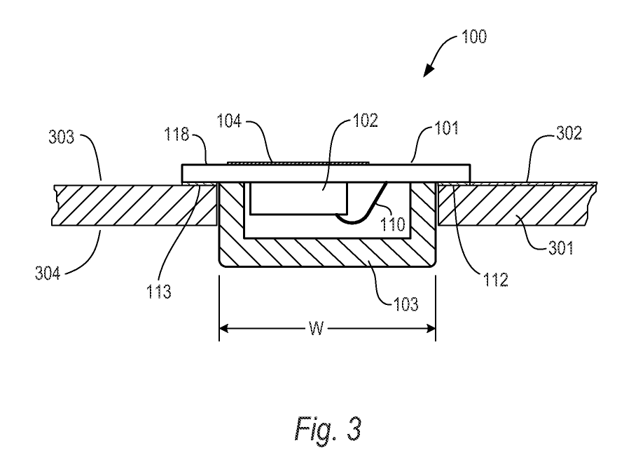

FIG. 3 is a cross sectional view of MEMS transducer device 100 mounted in a substrate 301 in accordance with a representative embodiment. As will be appreciated by one of ordinary skill in the art, MEMS transducer device 200 depicted in FIGS. 2A-2B could be mounted in substrate 301 by techniques described presently.

The substrate 301 has an opening having a width “w” as depicted in FIG. 3. The circuit traces 302 are electrically connected to contacts 112 of the package substrate 101 so that electrical signals can be transmitted to and from the transducers 106. The contacts 112 are normally soldered to the circuit traces on the substrate 301. The connection pads 113 are also soldered to the substrate 301 to mechanically fasten the MEMS transducer device 100 to the package substrate 101.

In a representative embodiment, the substrate 301 is a circuit board (e.g., FR4) having circuit traces 302 disposed over a first side 303 of the substrate 301. Additionally, electronic components (not shown) and electrical circuitry (not shown) useful in the transmission and reception of signals by the transducers 106 is provided over the first side 303 or over a second side 304 of the substrate 301, or both. In operation, mechanical waves can be transmitted from the transducers 106 through the screen 104 disposed along a second side 303 of the substrate 301. Likewise, mechanical waves can be received by the transducers 106 after traveling through the screen 104.

The width “w” of the opening is selected to allow the cover 103 to pass through the opening, but not wide enough for the package substrate 101 to pass through the opening. Moreover, the contacts 112 are located to ensure alignment with circuit traces 302 as needed. The contacts 112 and connection pads 113 allow for surface mounting of the MEMS transducer device 100 with all electrical and mechanical connections to the end application PCB board. Beneficially, no interconnect leads are required to mount the MEMS transducer device 100, thereby foregoing costly lead forming processes (so-called “trim and form”) during fabrication. Moreover, because the MEMS transducer device 100 is surface mountable, the MEMS transducer device 100 is readily adapted to high volume pick/place (e.g., robot) assembly used to assemble “mass-reflowable” electronic products. Beneficially, the reflowed solder will wet both electrical traces on the substrate 301 and on the package substrate 101 to form electrical connections as required.

In alternative embodiments in which a plurality of transducer substrates 102 are provided over a common package substrate 101, the width “w” of the opening would be wide enough for the common cover or the individual covers to pass through the opening in the substrate 301, but not wide enough for the common package substrate 101 to pass through the opening. Accordingly, the MEMS transducer device 100 is self-aligned to the substrate 301 and surface mounted thereto.

The various components, materials, structures and parameters are included by way of illustration and example only and not in any limiting sense. In view of this disclosure, those skilled in the art can implement the present teachings in determining their own applications and needed components, materials, structures and equipment to implement these applications, while remaining within the scope of the appended claims.

1. A micro-electromechanical systems (MEMS) transducer device mounted to a substrate, the MEMS transducer device comprising:
a package substrate having a first coefficient of thermal expansion (CTE); and
a transducer substrate comprising a transducer, the transducer substrate being disposed over the package substrate, wherein the transducer substrate has a second CTE that substantially matches the first CTE.

2. A MEMS transducer device as claimed in claim 1, further comprising an opening in the package substrate configured to receive and to transmit mechanical waves from the transducer.

3. A MEMS transducer device as claimed in claim 2, further comprising a screen disposed over the opening in the package substrate.

4. A MEMS transducer device as claimed in claim 1, further comprising an integral screen in the package substrate, wherein the transducer substrate is disposed over the integral screen.

5. A MEMS transducer device as claimed in claim 1, wherein the transducer substrate comprises silicon and the package substrate comprises alumina or sapphire.

6. A MEMS transducer device as claimed in claim 1, further comprising a cover disposed over the transducer substrate and substantially enclosing the transducer substrate over the package substrate.

7. A MEMS transducer device as claimed in claim 6, wherein the cover is configured to extend through an opening in the substrate.

8. A MEMS transducer device as claimed in claim 1, further comprising connection pads disposed over the package substrate and configured to bond to respective connection pads over the substrate.

9. A MEMS transducer device as claimed in claim 1, wherein the package substrate has a first side and a second side and the transducer substrate is provided over the first side.

10. A MEMS transducer device as claimed in claim 9, wherein a shield is disposed over the second side.

11. A micro-electromechanical systems (MEMS) transducer device, comprising:
a package substrate having a first coefficient of thermal expansion (CTE);
a transducer substrate comprising a transducer, the transducer substrate being disposed over the package substrate, wherein the transducer substrate has a second CTE that substantially matches the first CTE.

12. A MEMS transducer device as claimed in claim 11, further comprising an opening in the package substrate configured to receive and to transmit mechanical waves to and from the transducer.

13. A MEMS transducer device as claimed in claim 12, further comprising a screen disposed over the opening in the package substrate.

14. A MEMS transducer device as claimed in claim 11, further comprising an integral screen in the package substrate, wherein the transducer substrate is disposed over the integral screen.

15. A MEMS transducer device as claimed in claim 11, wherein the transducer substrate comprises silicon and the package substrate comprises alumina or sapphire.

16. A MEMS transducer device as claimed in claim 11, wherein further comprising a cover disposed over the transducer substrate and substantially enclosing the transducer substrate over the package substrate.

17. A MEMS transducer device as claimed in claim 16, wherein the cover comprises posts configured to secure the cover to the package substrate.

18. A MEMS transducer device as claimed in claim 11, wherein the package substrate has a first side and a second side and the transducer substrate is provided over the first side.

19. A MEMS transducer device as claimed in claim 18, wherein a shield is disposed over the second side.

20. A MEMS transducer device as claimed in claim 19, wherein the shield is connected electrically to ground.
